(19) United States
(12) Patent Application Publication
(10) Pub. No.: US 2026/0289040 A1
(43) Pub. Date: Sep. 24, 2026

(54) Test and measurement system for evaluating machine learning models of one or more test devices, test and measurement method, and computer program

(71) Applicant: Rohde & Schwarz GmbH & Co. KG, Munich (DE)

(72) Inventors: Michael VOLIANSKI, Mering (DE); Timo MAYER, Munich (DE); Andreas OELDEMANN, Munich (DE); Francesco ROSSETTO, Vaterstetten (DE)

(21) Appl. No.: 19/561,581

(22) Filed: Mar. 10, 2026

(30) Foreign Application Priority Data
Mar. 18, 2025 (DE) 102025110461.1

(51) Int. Cl. G06F 30/20

(52) U.S. Cl. CPC G06F 30/20

(57) ABSTRACT

A test and measurement system for evaluating learning models of one or more test devices, a test and measurement method, and a computer program are proposed. A test and measurement system (100) for evaluating learning models of one or more test devices (102; 104; 106; 108), comprising a test and measurement device (10), comprises one or more interfaces (12) configured to communicate data with the one or more test devices (102; 104; 106; 108). The test and measurement device (10) further comprises one or more computing units (14) configured to generate stimuli data for the one or more test devices (102; 104; 106; 108). The one or more computing units (14) are configured to provide the stimuli data to the one or more test devices (102; 104; 106; 108) via the one or more interfaces (12) to train one or more local machine learning models by the one or more test devices (102; 104; 106; 108) based on the stimuli data, and to receive, from the one or more test devices (102; 104; 106; 108), learning model data about the one or more trained machine learning models via the one or more interfaces (12). The one or more computing units (14) are configured to evaluate a quality of the one or more trained machine learning models based on the learning model data.

### TECHNICAL FIELD

The present disclosure relates to a test and measurement system for evaluating machine learning models of one or more test devices, a test and measurement method, and a computer program, in particular, but not exclusively, a concept for assessing a quality of trained learning models in test devices that are integrated in a distributed machine learning concept in a mobile radio system.

### BACKGROUND

Distributed machine learning plays a central role, for example, in 3GPP systems (3rd Generation Partnership Project) in the optimization and further development of modern mobile radio networks. With the introduction of 5G (5 th Generation) and the future 6G networks, machine learning methods are becoming increasingly important, in particular for network management, resource allocation, and predictive maintenance. One of the key challenges is to analyze large amounts of network information in real time and to derive patterns therefrom, without compromising the privacy of the users. Distributed learning allows models to be trained directly on the terminal devices or at the network edges (edge nodes), instead of collecting all raw data centrally. This not only reduces the data traffic in the network, but also increases the security and efficiency of the data processing.

A concrete example of the use of distributed machine learning in 3GPP networks is federated learning. Individual models are trained on local nodes before the aggregated parameters are transmitted to a central server in order to carry out a global model update. This approach is particularly advantageous for applications such as adaptive modulation and coding (AMC) or for optimizing handovers between radio cells. Since the calculations are carried out decentrally, network operators may offer a personalized user experience without passing on the underlying user data to central servers. This makes an important contribution to compliance with the data protection guidelines and to reducing latencies.

In addition to network control, distributed machine learning is also used in security mechanisms. Thus, anomalies in network traffic may be detected by local models and potential threats such as DDoS attacks (distributed denial of service) may be identified early. The combination of edge computing and machine learning results in robust mechanisms for attack detection, which may adapt dynamically to new threat scenarios. Future 6G systems will further expand this approach and enable an even greater integration of AI-based optimization mechanisms into network operation. The standardization work in 3GPP is therefore crucial to develop interoperable and efficient solutions for distributed machine learning in mobile radio networks.

### SUMMARY

There may be a demand for providing an improved concept for a test and measurement system, a test and measurement method, a computer program and a machine-readable medium.

Such a demand may be satisfied by the subject matter of any of the claims.

Embodiments of the present disclosure are based on the core idea that the quality of distributed learning models that train individual devices integrated in a distributed machine learning is decisive for the overall quality or the overall benefit of a distributed machine learning algorithm. Another finding is that training of a learning model in a test device by providing corresponding stimuli data and subsequent evaluation of the learning model may be checked and also evaluated in a targeted manner using a test device. Multiple test devices may also be integrated in the process, so that the effects of distributed machine learning may be assessed.

Embodiments provide a test and measurement system for evaluating machine learning models of one or more test devices. The system comprises a test and measurement device having one or more interfaces for communicating data with the one or more test devices. The test and measurement device further comprises one or more computing units configured to generate stimuli data for one or more test devices and to provide the stimuli data to the one or more test devices via the one or more interfaces to train one or more local machine learning models by the one or more test devices based on the stimuli data. Further, the test and measurement device is configured to receive, from the one or more test devices, learning model data about the one or more trained machine learning models via the one or more interfaces, and to evaluate a quality of the one or more trained machine learning models based on the learning model data. In this respect, the system allows testing or evaluating a quality of the learning models trained in the test devices.

The test and measurement device may further be configured to aggregate, via the learning model data from the one or more test devices, the one or more local learning models and to evaluate the quality of the local machine learning models based on the aggregated data and/or an aggregated model. In this respect, a quality of the aggregated learning model, i.e. the learning model based on multiple trained learning models of multiple test devices, may also be evaluated. Additionally or alternatively, the test and measurement device may also have the opportunity to simulate one or more additional clients (further (test) devices) to obtain additional machine learning models and to aggregate the machine learning models from the one or more test devices and the additional machine learning models and to evaluate the quality of the local learning models based on the aggregated data and/or the aggregated machine learning model. In this respect, by combining actual and simulated learning models and/or their data, a number of trained learning models may be generated which allow evaluation of aggregated learning models (learning models based on aggregated data), in particular also if the number of aggregated learning models is high (for example more than 5, 10 or 50 test devices).

In further embodiments, the test and measurement system may further comprise a radio frequency interface or an emulator for a radio frequency interface to establish a connection with the one or more test devices. As a result, more realistic conditions for the test may be created, since genuine or emulated radio frequency effects may also be taken into account. One or more ports for coupling the one or more test devices via a radio frequency cable may also be provided for this purpose. The system may optionally also comprise a server simulator for simulating a federated learning data server in cooperation with the one or more test devices configured to exchange data with the one or more test devices. In this respect, a learning model which is ultimately trained in an aggregated manner by a server based on the data of the test devices may also be evaluated and/or tested. In some embodiments, the test and measurement system may also comprise a uni- or bidirectional channel simulator for simulating a time-variable or time-constant transmission channel between the test and measurement device and the one or more test devices. For example, the channel simulator may be configured to simulate one or more effects from the group of linear distortions, non-linear distortions, bit errors, communication delays, and/or data throughput limitations. In this respect, embodiments may also take into consideration realistic effects of a mobile radio channel in a cost-effective manner in the evaluation.

For example, in further embodiments, the test and measurement system may optionally also comprise one or more device simulators for simulating one or more additional devices with additional learning models. The device simulator may be configured to simulate, as an additional device, one or more elements of the group of one or more further test devices, one or more reference devices, one or more unreliable devices, one or more interfering devices, or one or more adversary/attacking devices. In embodiments, influences of further devices having different properties or intentions may also be taken into consideration in the evaluation in this way. Further, the device simulator may be configured to receive, via a software interface, a user-defined model specification, a user-defined model training, a specification for a model test, and/or a user-defined trained model. In this respect, user-specific models may be taken into consideration in the simulation of additional devices. In some embodiments, the test and measurement system comprises a software interface for communicating a user-defined model specification and/or a specification for a model test. User-specific settings, specifications, or even preferences may then be taken into account in the evaluation. A software interface may also be used for importing a user-defined trained model. Further, one or more software interfaces may also be provided for communicating a user-defined model specification, a user-defined model aggregation, and/or a specification for a model test. In this respect, extensive influence options may be offered to the user in some embodiments.

The test and measurement system may also comprise a monitoring and reporting unit. This allows a user to be directly informed by the device. The monitoring and reporting unit may be configured to display reporting positions on a built-in display. In this respect, results may be displayed directly at the test and measurement device. For example, the monitoring and reporting unit is configured to monitor and report the order of the transmission of the data required for the training process, if applicable a time of a transmission of the data required for the training process, the frequency of a transmission of the data required for the training process, the size of the packets used for the transmission of the data required for the training process, and/or qualitative/quantitative parameters indicating the progress of the training. A user may thus be offered a variety of evaluation options.

Further, one or more ports for coupling the one or more test devices via a radio frequency cable may be provided. Alternatively, a communication via radio over the air interface is of course also conceivable. In this respect, a signal processing in the radio frequency range may be included in the evaluation. In general, in embodiments, the one or more additional components described herein (e.g. simulation and/or communication components) of the test and measurement system (simulators, units, etc.) may be fixedly installed in the test and measurement device, and the test and measurement system may be equipped with an interface for communicating with the one or more test devices. In a further embodiment, the test and measurement system is coupled to one or more test devices.

Embodiments further provide a test and measurement method for evaluating learning models of one or more test devices. The method comprises generating stimuli data for the one or more test devices, wherein the one or more test devices use machine learning models, and providing the stimuli data to the one or more test devices to train one or more machine learning models based on the stimuli data. The method further comprises receiving learning model data about the one or more trained machine learning models from the one or more test devices, and evaluating a quality of the one or more trained machine learning models based on the learning model data.

A further embodiment is a computer program and/or a machine-readable medium having a program code for performing one of the methods described herein when the program code is executed on a computer, a processor, or a programmable hardware component.

### BRIEF DESCRIPTION OF THE FIGURES

Some examples of apparatuses, methods, and/or computer programs are explained in more detail below merely by way of example with reference to the accompanying figures, in which:

FIG. 1 shows a block diagram of an embodiment of a test and measurement system for evaluating learning models of one or more test devices;

FIG. 2 shows a flow chart of an embodiment of a method for evaluating learning models of one or more test devices;

FIG. 3 shows an embodiment with distributed learning and a parameter server;

FIG. 4 shows an embodiment with decentralized distributed learning; and

FIG. 5 shows a further embodiment of a test and measurement system.

### DESCRIPTION

Some examples are now described in more detail with reference to the enclosed figures. However, other possible examples are not limited to the features of these embodiments described in detail. These may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may, in each case, be identical or implemented in a modified form while providing the same or a similar function. The thickness of lines, layers and/or areas in the figures may also be exaggerated for clarification.

When two elements A and B are combined using an ‘or’, this is to be understood as disclosing all possible combinations, i.e., only A, only B as well as A and B, unless expressly defined otherwise in the individual case. As an alternative wording for the same combinations, “at least one of A or B” or “A and/or B” may be used. This applies equivalently to combinations of more than two elements.

If a singular form, such as “a,” “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

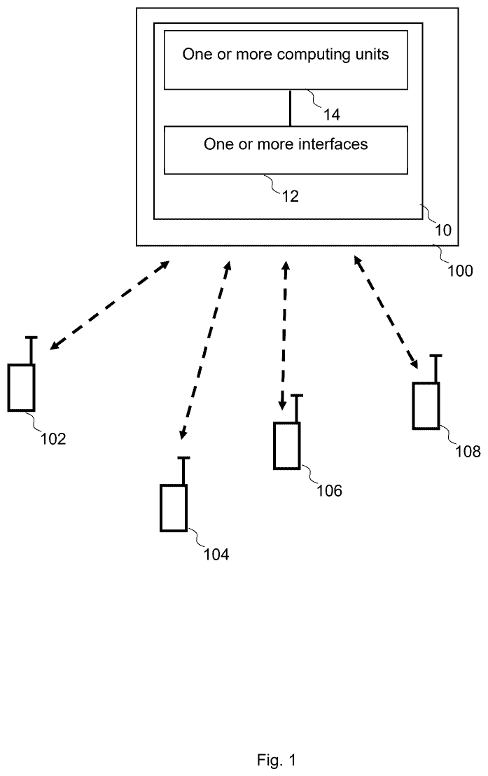

FIG. 1 shows a block diagram of an embodiment of a test and measurement system 100 for evaluating machine learning models of one or more test devices 102, 104, 106, 108. The test and measurement system 100 comprises a test and measurement device 10 having one or more interfaces 12 for communicating data with the one or more test devices 102-108. The one or more interfaces 12 are coupled to one or more computing units 14. The one or more computing units 14 are configured to generate stimuli data for the one or more test devices 102-108. The one or more test devices 102-108 use machine learning models. It is provided that the stimuli data are provided to the one or more test devices 102-108 via the one or more interfaces to train one or more local machine learning models by the one or more test devices 102-108 based on the stimuli data. The one or more computing units 14 are further configured to receive, from the one or more test devices 102-108, learning model data about the one or more trained machine learning models via the one or more interfaces 12. Finally, the one or more computing units 14 are configured to evaluate a quality of the one or more trained machine learning models based on the learning model data.

For example, in telecommunication systems, such as 3GPP systems, various learning models are used for distributed machine learning to optimize network capacities, improve security mechanisms and develop energy-efficient communication strategies. A particularly common approach is federated learning (FL), in which models are trained locally on individual devices or network nodes without the raw data being transmitted to a central entity. This enables a data protection-friendly optimization of mobile radio networks, for example, to improve the resource allocation or to predict network utilization. By iterative aggregation of the locally trained models, a central control unit may derive a global model without directly accessing the user data.

A further relevant concept is split learning, in which the training of a neural network is split between terminal devices and central servers. While the first layers of the neural network are processed locally on the device, the further processing of deeper network structures is carried out on powerful servers. This allows a balance between data protection and computing power, in that only abstract feature representations are transmitted, instead of sensitive raw data. This method is particularly suitable for applications such as predictive network maintenance or the personalized provision of network services based on user behavior. The combination of these various learning models considerably increases the efficiency of 3GPP mobile radio networks and creates a future-oriented network infrastructure.

A learning model in the context of machine learning, in particular in distributed machine learning in 3GPP systems, is described by various data categories. First of all, the model architecture is a central aspect which defines the type of model such as neural networks, decision trees or support vector machines (SVM). In addition, this includes the number of layers and neurons, the activation functions used, such as ReLU or Softmax, and various hyperparameters, including learning rate, batch size and regularization methods. The weight initialization and the parameter distribution also play an important role, since they may influence the convergence and performance of the model.

In addition to the architecture, the training methodology is also crucial for the performance of a learning model. This includes the description of the data set, including the type, amount and source of the data, such as, for example, sensor data from 5G networks or mobility patterns of users. The preprocessing of the data is carried out by normalization, feature engineering or data augmentation. Depending on the type of learning—be it monitored, unmonitored or reinforcing learning—different optimization algorithms, such as Stochastic Gradient Descent (SGD) or Adam, are used. For the evaluation of the model, metrics such as accuracy, precision, recall and the F1 score are used, while the loss function, for example mean square error (MSE) or cross-entropy, controls the adaptation of the model to the training data.

In embodiments, the test and measurement system first provides stimuli data to the test devices. The data may be training data or input data for the learning model used by the respective test device. These stimuli data are then supplied to the learning model of the test device, for example by training or inputting, to obtain corresponding output values. At least in some embodiments, the learning model is also modified, for example trained, by corresponding input data which also contain information per se.

A learning model is represented by various parameters which determine its structure, mode of operation and performance. In principle, these parameters may be divided into three categories: model parameters, hyperparameters and evaluation metrics.

The model parameters are values which are learned during the training process. These include, in particular, the weights and bias values of a neural network which determine the strength and direction of the connections between the neurons. These parameters are iteratively adapted by optimization methods, such as Stochastic Gradient Descent (SGD) or Adam, in order to minimize the error of the predictions. In addition, feature coefficients play a central role in linear models or decision limits in classification models, since they influence the representation of the data in the model.

In contrast, the hyperparameters are not learnable by training, but must be defined in advance. This includes the learning rate which determines how much the model parameters change per iteration. A learning rate which is too high may lead to instabilities, while one which is too low may cause convergence problems. Further important hyperparameters are the batch size, which determines the number of training examples per optimization step, and the number of layers and neurons in neural networks which define the model complexity. Likewise, the choice of the activation functions (e.g. ReLU, Sigmoid, Softmax) and the regularization methods (e.g. L1/L2 regularization, Dropout) influence the generalization capability of the model.

In addition to the model and hyperparameters, evaluation metrics may also play a role in the description of a learning model. These include the loss function (e.g. mean squared error for regression or cross-entropy for classification) which measures the difference between the predicted and the actual values. Furthermore, performance metrics such as accuracy, precision, recall and the F1 score are used to evaluate the quality of the predictions. In continuously learning systems, adaptation parameters such as learning rate adaptation or early stopping are also relevant to avoid overadaptation and to ensure an efficient training strategy.

These parameters together determine the efficiency, accuracy and possibilities of use of a learning model, in particular in distributed machine learning methods such as those used in 3GPP networks.

Finally, runtime and operating data are also important, in particular for the integration of the model into a distributed system. The model size influences the memory consumption, while the computational complexity is evaluated on the basis of FLOPS (floating point operations per second) or the latency per prediction. In edge computing environments, energy consumption is a critical factor, since mobile devices have only limited resources available. The adaptability of a model determines whether it may be updated continuously or incrementally in order to adapt to new network requirements. Depending on the environment of use—be it on edge servers, mobile devices or in the cloud—mechanisms for data protection and aggregation must also be taken into account in order to ensure the security of sensitive user data. In embodiments, the test devices obtain the stimuli data and supply them to their learning models. The test devices then communicate learning model data back to the test and measurement system. The learning model data may include any parameters, weights, feature vectors or other parameters describing the learning model.

The test and measurement system may then perform an evaluation of the learning models on the basis of the learning model data. For example, effects which a training with the stimuli data has on a learning model may be traced and/or evaluated.

The test devices 102-108 may be terminal devices of a mobile radio system, which are typically referred to as UE (user equipment) or as DUT (device under test). The field of application for the test and measurement system therefore addresses, in particular, mobile radio devices of modern telecommunications networks, such as those specified by 3GPP, such as, for example, 5G, 6G, and subsequent generations. An evaluation of the learning models is relevant, in particular, in an implementation of distributed machine learning systems, as will be explained in more detail below.

The quality of a learning model may be evaluated on the basis of various metrics and methods which measure both the accuracy and the generalization capability of the model. Basically, these may be divided into performance metrics, validation methods and robustness analyses which may be carried out on the basis of the learning model data. An essential aspect of the evaluation are the performance metrics which vary depending on the case of use. In the case of classification models, the Accuracy which determines the proportion of the correctly predicted classes is frequently used. However, this metric is not always meaningful in the case of unbalanced data sets, which is why supplementary metrics such as Precision, Recall and the F1 score are used. While Precision indicates the proportion of the actually relevant positive predictions, Recall measures how many of the actually positive cases have been correctly detected. The F1 score combines both measures as a harmonic mean and is particularly suitable for scenarios with unbalanced class distributions. In regression models, on the other hand, mean square error (MSE) or mean absolute error (MAE) are used which determine the average deviation between predicted and actual values.

In addition to the performance metrics, a validation may be crucial for the evaluation of the model quality. A common method is cross-validation, in which the data set is split into multiple subsets, so that the model is iteratively evaluated on different training and test sets. The holdout method, in which a fixed part of the data is reserved for the testing, represents a simpler alternative. In order to detect overfitting, the train-test error comparison is often carried out: a model having a significantly lower error on the training data in comparison with the test data may have a lack of generalization capability.

In addition, the robustness of the model may be analyzed in order to ensure that it functions well not only on specific training data. This includes adversarial testing, in which specifically modified inputs are tested to check the stability of the predictions, as well as fairness and bias analyses which ensure that the model does not have any unwanted distortions. The computational complexity, including the latency per prediction and the memory consumption, is also a crucial quality criterion, in particular for models which are used in real-time systems such as 3GPP networks.

The combination of these evaluation methods makes it possible to obtain a comprehensive picture of the quality of a learning model and to ensure that it is both powerful and capable of generalization for real-world applications.

In embodiments, the one or more interfaces 12 of the test and measurement device 10 may correspond to any means for obtaining, receiving, transmitting or providing analog or digital signals or information, e.g. a plug, contact, pin, register, input terminal, output terminal, conductor, track, antenna, etc., which enables the provision of a signal. An interface may be wireless or wired, and it may be configured such that it communicates with further internal or external components, i.e. transmits or receives signals or information. In the present case, the one or more interfaces 12 may be configured, for example, to transmit information about the stimuli data and the learning model data, at least in part. In general, the one or more interfaces enable communication between the test and measurement device 10 and further components of the test and measurement system 100 and/or with the test devices 102, 104, 106, 108. In this case, they may also make use of mobile radio networks or other wireless network accesses and include corresponding transmitter components, receiver components, gateways, etc.

In embodiments, the one or more computing units 14 may be configured for digital signal processing. They may be implemented as one or more processing units, one or more processing devices, any means for processing, any means for determining, any means for calculating, such as a processor, a computer, or a programmable hardware component, which may be operated with correspondingly adapted software. For example, the one or more computing units may also include memories which store corresponding queries, query catalogs, responses, instructions, etc. The described function of the one or more computing units 14 may also be implemented in software which is then executed on one or more programmable hardware components. Such hardware components may comprise a general-purpose processor, a digital signal processor (DSP), a microcontroller, etc.

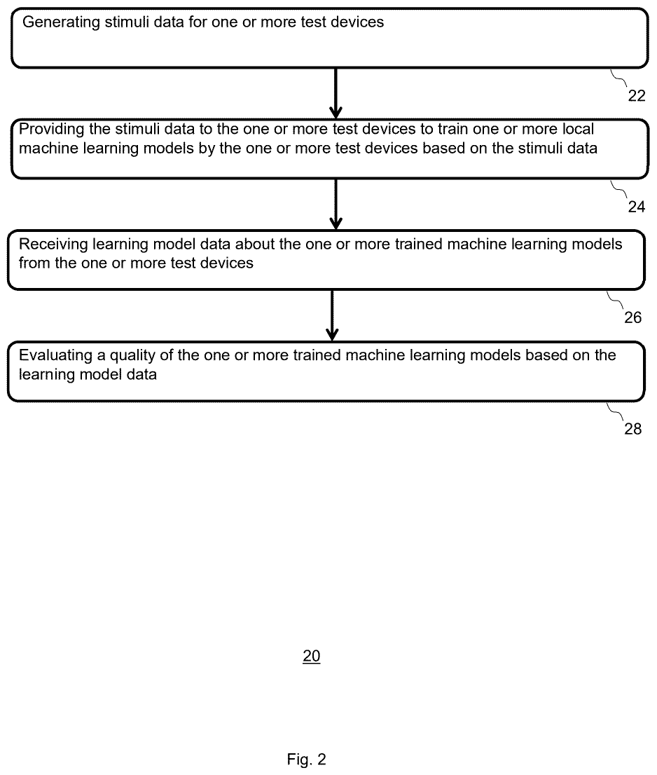

FIG. 2 illustrates a flow chart of a test and measurement method 20 for evaluating learning models of one or more test devices 102-108. The method 20 comprises generating 22 stimuli data for one or more test devices 102-108, wherein the one or more test devices 102-108 use machine learning models. The method 20 further includes providing 24 the stimuli data to the one or more test devices 102-108 to train one or more machine learning models based on the stimuli data. This is followed by receiving 26 learning model data about the one or more trained machine learning models from the one or more test devices 102-108, and finally evaluating 28 the quality of the one or more trained machine learning models based on the learning model data.

Embodiments provide a test system for federated or distributed learning in wireless communication networks. Machine learning is an essential element for 5G and later generations of mobile radio networks. Possible fields of application of distributed learning and federated learning are, for example, improvement of power control, resource allocation, selection of a modulation and coding scheme, selection of QoS parameters (quality of service), etc. So far, application possibilities have not been standardized or specified.

Embodiments do not make any difference between distributed and federated learning and/or between online and offline training. The term “distributed learning” is used both for distributed and for federated learning.

Two categories may be distinguished here:
distributed learning with parameter server, and
decentralized distributed learning.

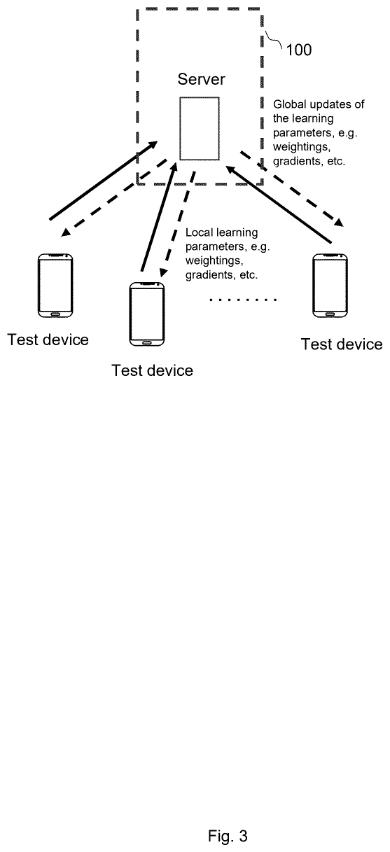

The distributed learning with parameter server is shown in FIG. 3. FIG. 3 shows an embodiment with distributed learning and a parameter server. FIG. 3 shows multiple test devices communicating local learning parameters, e.g., weightings, gradients, etc., to a server, which is indicated by the solid arrows. The server evaluates the data and communicates global updates of the learning parameters, e.g., weightings, gradients, etc., back to the test devices, which is indicated by the dashed arrows in FIG. 3. The measurement system 100 intervenes precisely in these interfaces and may monitor a corresponding communication and draw corresponding conclusions for the evaluation of the learning models in the test devices.

Each agent/(test device) trains its own local model. The (intermediate) results of the training, e.g., model weightings or gradients, are uploaded to the server. The server summarizes the uploaded data and sends a global update to each of the agents. Precisely this behavior may also be imitated by the test and measurement device 10. Thus, the test and measurement device 10 may further be configured to aggregate (summarize) the learning model data and/or the one or more local learning models from the one or more test devices and to evaluate the quality of the local machine learning models based on the aggregated data and/or the aggregated learning model. In further embodiments, the test and measurement device may also be configured to simulate one or more additional clients (agents, test devices, or also the server) to obtain additional learning model data, to aggregate the machine learning model data (learning models) from the one or more devices and the additional learning model data (learning models) and to evaluate the quality of the learning models based on the aggregated data and/or the aggregated learning model. In the present embodiment, the stimuli data for the test devices may accordingly also include the data communicated by the server. As will be explained in more detail below, the test and measurement system 100 may include various further components, in particular simulators for various network components, in order to provide the test devices with a testing environment that is as realistic as possible. For example, the test and measurement system 100 may further comprise a server simulator for simulating a federated learning data server in cooperation with the one or more test devices 102-108 configured to exchange data with the one or more test devices.

Although apparent at first glance, the server is not necessarily implemented in a base station of the mobile radio system in the centralized model (FIG. 3). It could also be implemented in a terminal device, e.g. if a terminal device manufacturer does not wish to share its proprietary know-how with other manufacturers and/or manufacturers of base station devices.

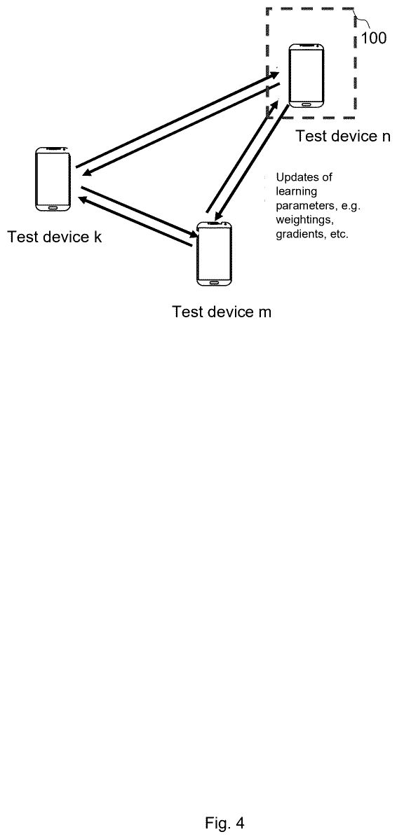

A completely decentralized learning is shown in FIG. 4. FIG. 4 shows an embodiment with decentralized distributed learning. FIG. 4 first shows three agents or test devices k, m, and n exchanging updates of learning parameters, e.g., weightings, gradients, etc., with each other. Each agent (test device) trains its own local model. The (intermediate) results of the training, e.g., model weightings or gradients, are sent to the neighbors of the agent. After receiving the updates, each agent summarizes the uploaded data and sends an update to its neighbors. As FIG. 4 further shows, the test and measurement system 100 may take the place of an agent (test device) in order to evaluate the learning models of the test devices k and m communicating with it on the basis of the updates. In this case, the stimuli data are learning model data of the test device n simulated in the test and measurement system.

The training of a two-sided model, e.g., for CSI compression, may also be interpreted as decentralized distributed learning with two agents. With regard to further details on methods and applications of distributed learning as such, reference is made, e.g., to https://ieeexplore.ieee.org/document/9446488.

Embodiments of the measurement system 100 either perform measurements which are common for the most probable applications and/or provide a precisely defined and reproducible environment which is required for performing such tests and/or measurements.

The tests which are common for most applications include, inter alia, the logging of the communication packets between agents or between agents and the server, the measurement of the frequency of updates, the total communication volume, the overhead caused by the training, the reaction times, the latency times, etc.

The well-defined and reproducible environment includes, inter alia (but not exclusively), a time-varying, possibly lossy channel, imperfect analog hardware, processing delays (including communication latency), restrictions on the available bandwidth or the maximum throughput, etc. The environment may also simulate additional traffic, inter alia, from unreliable and/or adversarial agents.

The results of the tests are either displayed or evaluated in the measurement device or transmitted to an external interface for further evaluation.

Thus, in embodiments, for example, a machine learning model (also ML model) for channel estimation may be trained by the test devices (DUT) on the basis of downlink channel realizations which were generated by the test and measurement system 100. Furthermore, in further embodiments, the test and measurement system 100 may further comprise a uni-or bidirectional channel simulator for simulating a time-variable or time-constant transmission channel between the test and measurement device 10 and the one or more test devices. The channel simulator may be configured, for example, to simulate one or more effects from the group of linear distortions, non-linear distortions, bit errors, communication delays, and/or data throughput limitations. For example, a wireless downlink with fast fading is simulated. The channel simulator may accordingly be configured to simulate the RF channel at various depths of detail. Analog hardware may also be used in this case. For example, bit errors may be simulated in the data used for the training as well as activation and/or reaction times, so that laggard problems may also be analyzed. Such effects may also be simulated and/or caused by bandwidth limitation.

In some embodiments, the test and measurement system 100 may further comprise a radio frequency interface (RF interface) or an emulator for a radio frequency interface to establish a connection with the one or more test devices and/or to emulate/simulate an RF connection. For example, the transmission of baseband IQ values may be carried out here via an IP connection and a baseband transmission may be simulated accordingly. In some embodiments, at least one RF connection may thus be established between the test object(s) (one or more test devices) and the test and measurement device 10 or at least to an emulator of an RF connection between the DUT(s) and the test and measurement device 10.

As already described above, at least in some embodiments, the test and measurement system 100 may also comprise one or more device simulators for simulating one or more additional devices with additional learning models.

A device simulator may be implemented, for example, as specialized hardware, as a specialized software environment, or as a specialized hardware/software combination. The device simulator allows the functions and behaviors of a real-world device (e.g., mobile device, test device, reference device, etc.) to be simulated virtually by emulating essential hardware components which are involved in machine learning, and communication interfaces to mobile radio networks, WLAN, and Bluetooth. As a result of this realistic simulation, various deployment scenarios, for instance, different network latencies, reception strengths, or user interactions, may be implemented risk-free and efficiently via the test and measurement system, without being dependent on physical devices. This not only promotes the early identification and correction of errors, but also enables a targeted optimization of applications, which ultimately leads to a shortened development time and a higher quality of the end product. In particular, further devices involved in a federated learning process may be simulated.

The device simulator may be configured to simulate, as an additional device, one or more elements of the group of one or more further test devices, one or more reference devices, one or more unreliable devices, one or more interfering devices, and/or one or more adversarial devices (attackers). In this way, additional learning model data for central aggregation may be generated. For example, comparison or reference data may come from a reference device in order to specify an evaluation basis for the (aggregated) learning model data. In general, it is thus also possible to create a more realistic test environment since, on the one hand, unreliable data may also be included and possible limitations of the usable communication bandwidth may be taken into account. An adversarial or attacking device may, for example, include maliciously manipulated or generated data in the process in order to enable an evaluation also for these cases.

In further embodiments, a user-defined model specification, a user-defined model training, a specification for a model test, and/or a user-defined trained model may also be transmitted to the device simulator via a software interface. This allows a user to be provided with a variety of configuration and test options. For example, a model structure, a training algorithm, etc. may be specified to the simulator. In particular, the test and measurement system 100 may comprise a software interface for communicating a user-defined model specification, a user-defined model aggregation, and/or a specification for a model test, via which, for example, model structure and training algorithms may also be specified here. Further, a software interface for importing a user-defined trained model may also be present. The software interfaces described herein may be implemented jointly, in groups, or also individually, for example as a so-called API (application programming interface), and may also be part of the one or more interfaces 12 described above.

In some embodiments, the test and measurement system 100 may also comprise a monitoring and reporting unit. This may be configured, for example, to display reporting positions on a built-in display (monitor, display), to store them, and/or to output them via an interface. For example, the monitoring and reporting unit may be configured to monitor and report the order of the transmission of the data required for the training process, if applicable a time of a transmission of the data required for the training process, the frequency of a transmission of the data required for the training process, the size of the packets used for the transmission of the data required for the training process, and/or qualitative/quantitative parameters indicating the progress of the training. Thus, for example, a monitoring of model parameters and/or model updates may be carried out.

The components described herein, such as, for example, interfaces, simulators, displays, etc., may be present modularly in the test and measurement system, they may be exchangeable or also fixedly installed in the test and measurement device 10. In some embodiments, the system 100 may be implemented as a measurement device in one piece (one-box) with fixedly integrated components. The individual components may be equipped with an interface for communicating with the one or more test devices, in which case there may be both multiple individual interfaces and common interfaces. Within the test and measurement system 100, further interfaces for communication of the components with one another may further be present in some embodiments. In testing and measurement operation, the test and measurement system is then coupled to the one or more test devices via the corresponding one or more interfaces.

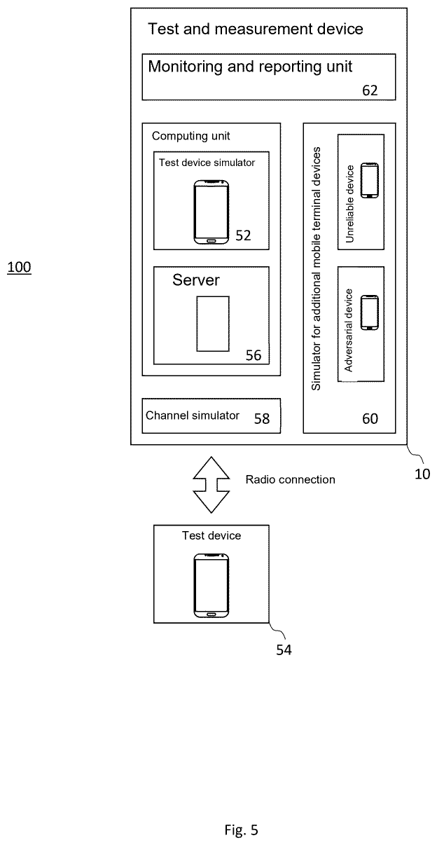

The measurement setup for an embodiment of a test and measurement system 100 is shown in FIG. 5. The test and measurement system 100 comprises multiple computing units in the present case. The processing unit 10 (test and measurement device) contains a simulator (test device simulator 52) for at least one agent (simulated test device), which participates in the distributed learning together with the test object (test device 54). The server simulator 56 simulates, for example, a server at the base station in the case of distributed learning with a parameter server.

The channel simulator simulates the well-defined and reproducible environment. The simulator 60 for additional mobile terminal devices optionally simulates additional traffic, adversarial and/or unreliable agents. The results are evaluated by the monitoring and processing unit 62.

The previous description dealt primarily with the functionality of the measurement system 100. The data transmission between the test device and the measurement system will be considered in more detail below.

Embodiments may provide a conformity or production test of the (online) federated or distributed learning capabilities of a mobile terminal device. For this purpose, a system for testing and measuring one or more DUT(s) (test devices) is created, which contains at least one machine learning algorithm. For this purpose, a machine learning algorithm is executed which may be implemented, for example, as a neural network. The system comprises at least one processing unit (computing unit) which repeatedly receives (at least once) (possibly intermediate) data which were generated during an iteration of the training process of the DUT(s) and calculates the data which are required for the next iteration of the training process, and transmits the calculated data to the DUT(s) (stimuli data). These data contain, for example, model weightings, gradients, etc. Updates of weightings, gradients may also be transmitted in the following. Optionally, there may be a (simulated or specified) reference device which may be used for comparison or as an evaluation scale (benchmarking). Furthermore, at least one RF connection may be established between the test object(s) and the test and measurement system and/or at least one emulator may be present which emulates an RF connection between the DUT(s) and the test and measurement equipment. Here, for example, the transmission of baseband IQ values may take place via an IP connection.

The system may optionally comprise a simulator for a server participating in the test to enable a model aggregation for a centralized model formation. In further embodiments, the system may have a channel simulator which simulates uni- or bidirectional, possibly time-variable transmission channels. The channel simulator simulates, for example, linear and/or non-linear distortions. Analog hardware may be used to simulate a radio channel. The channel simulator may additionally or alternatively simulate bit errors which may be present in the data used for the training. Further, communication delays may optionally be simulated, e.g., activation/reaction times, laggard problems, etc. The channel simulator may also simulate the data throughput limitation, which results, for example, from bandwidth limitation.

Additionally or alternatively, a simulator for additional mobile terminal devices may be provided, for example, for limiting the available bandwidth or for simulating an unreliable client (additional test device, terminal device). An additional mobile terminal device is, for example, an unreliable or an adversarial device which attempts to obstruct the learning algorithm or the training via manipulated data. This is also referred to as data poisoning. An additional mobile terminal device may also be a reference device in order to allow benchmarking. The simulator for a user terminal may also offer a software interface for a user-defined model specification and training, examples being model structure and training algorithm. The simulator for a user terminal may also offer a software interface for importing a user-defined trained model.

The processing unit may be fixedly installed in the test and measurement system, so that the system may be offered as a complete solution. Further, the processing unit may comprise one or more software interfaces for a user-defined model specification and training, e.g., model structure, training algorithm, etc. The simulator may further offer one or more software interfaces which are provided for importing a user-defined trained model.

The connection of the test devices to the test and measurement system may be carried out via an RF cable or also via radio over the air interface. The simulator for a server may also offer a software interface for a user-defined model aggregation. In further embodiments, a monitoring and reporting unit may be provided. The monitoring and reporting unit displays, for example, reporting positions on a built-in display and/or stores the data in files and/or outputs them on an external interface. In some embodiments, the monitoring and reporting unit monitors and reports, if applicable, the order of the transmission of the data required for the training process (e.g. model parameters, model updates). Times of the transmissions of the data required for the training process may be monitored and reported in this way. The monitoring and reporting unit optionally monitors and reports the frequency of the transmission of the data required for the training process. The size of the packets used for the transmission of the data required for the training process may also be monitored and/or reported. The monitoring and reporting unit monitors and reports, if applicable, qualitative and/or quantitative parameters indicating the progress of the training.

In the following, some concrete test scenarios are described. The following test setup is used for this purpose:
The test equipment (TE, test and measurement system) emulates a base station (with the device simulator) of a mobile radio system (e.g., a gNodeB);
one or more UEs are connected to the TE; and
one or more additional UEs may be simulated in the TE.

### 1. Test Case:

AI/ML (artificial intelligence/machine learning) CSI (channel state information) feedback compression (compression of the channel estimation response)

### Training:

The TE generates downlink channel data (stimuli data of a channel simulator) for one or more UEs (e.g., based on stochastic channel models, raytracing).
UEs train a complete autoencoder locally (e.g., based on a neural network (e.g., “fully connected neuronal networks” or “convolutional neuronal networks”)).
UEs transmit data (learning model data) to the TE which are required for the training of a suitable decoder (e.g., uncompressed input data and compressed data in the latent space).
The TE trains a suitable decoder which is interoperable with the encoders trained in the UEs.

### Monitoring/Surveillance:

The TE monitors the learning process of the UEs.
   monitoring the data exchange between TE and UEs and, if applicable, between the UEs (e.g., the time and the sequence of messages, the amount of data, the duration of the exchange, etc.).
The TE monitors the performance of the trained models and the evolution of the performance over time:
   measurement of the throughput in the downlink.
   measurement of the reconstruction accuracy of the decompressed CSI (e.g. cosine similarity). Ground-truth CSI (reference value) may be determined on the basis of the generated downlink channel (known data from the channel simulator). A quality measure for the learning models may be developed via the reconstruction accuracy.

### 2. Test Case:

A further test case is AI/ML positioning (localization) by means of fingerprinting of CIR (channel impulse response). The channel impulse response characteristic of a specific position is to be used to determine the position.

### Training:

The TE emulates a position in space by generating a corresponding downlink channel.
   The position may be specified by a user and is thus known as a label in the UEs.
   The position may be transmitted to the UEs as a label via a side channel (e.g., user data in the downlink, generated GPS (global positioning system) signal, picture).
The UEs train local models based on the estimated downlink channel and the position label.
The UEs send the trained local models back to the TE.
The TE aggregates the models learned by the UEs and sends the global model back to the UEs.

### Monitoring/Surveillance

The TE monitors the learning process of the UEs;
   monitoring the data exchange between TE and UEs and, if applicable, between the UEs (e.g., the time and the sequence of messages, the amount of data, the duration of the exchange, etc.)
If the UEs transmit the estimated position back to the TE, the TE may check the accuracy of the positioning on the basis of the known ground-truth position label and determine a measure for the quality of the estimated position and thus for the learning models.

### 3. Test Case:

A further test case is the channel estimation/MIMO (multiple-input-multiple-output) detection.

### Training:

The TE emulates a downlink channel including pilot symbols (e.g. 5G NR DMRS (new radio, demodulation reference symbols)).
The UEs use the pilot symbols for a non-AI/ML-based channel estimation/MIMO detection (e.g. least squares, maximum-likelihood). The pilot symbols and the result of the channel estimation/MIMO detection may be used by the UEs as a training data set for an AI/ML-based channel estimation/MIMO detection.
The UEs train local models for an AI/ML-based channel estimation/MIMO detection.
The UEs send the trained local models back to the TE.
The TE aggregates the models learned by the UEs and sends the global model back to the UEs.

### Monitoring/Surveillance

The TE monitors the learning process of the UEs;
   monitoring the data exchange between TE and UEs and, if applicable, between the UEs (e.g., the time and the sequence of messages, the amount of data, the duration of the exchange, etc.).
The TE monitors the performance of the trained models and the evolution of the performance over time.
   measuring the throughput in the downlink.

In general, the TE may cover the following aspects in various cases of use.
The TE emulates additional UEs, possibly including insecure and interfering UEs.
The TE emulates transmission delay.
The TE emulates data throughput over the channel.

The aspects and features described in relation to a particular one of the previous examples may also be combined with one or more of the further examples to replace an identical or similar feature of that further example or to additionally introduce the feature into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or comprise machine-executable, processor-executable or computer-executable programs and instructions. The program storage devices may comprise or be, for instance, digital memories, magnetic storage media such as magnetic disks and magnetic tapes, hard drives, or optically readable digital data storage media. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes or -operations.

If some aspects in the previous sections have been described in relation to a device or system, these aspects should also be understood as a description of the corresponding method. In this case, for example, a block, a device or a functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that—although in the claims a dependent claim refers to a particular combination with one or more other claims—other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A test and measurement system (100) for evaluating machine learning models of one or more test devices (102; 104; 106; 108), comprising a test and measurement device (10), comprising
one or more interfaces (12) configured to communicate data with the one or more test devices (102; 104; 106; 108); and
one or more computing units (14) configured to
generate stimuli data for the one or more test devices (102; 104; 106; 108),
provide the stimuli data to the one or more test devices (102; 104; 106; 108) via the one or more interfaces (12) to train one or more local machine learning models by the one or more test devices (102; 104; 106; 108) based on the stimuli data,
receive, from the one or more test devices (102; 104; 106; 108), learning model data about the one or more trained machine learning models via the one or more interfaces (12), and
evaluate a quality of the one or more trained machine learning models based on the learning model data.

2. The test and measurement system (100) of claim 1, wherein the test and measurement device is further configured to aggregate, via the learning model data from the one or more test devices (102; 104; 106; 108), the one or more local machine learning models and to evaluate the quality of the local machine learning models based on the aggregated machine learning model.

3. The test and measurement system (100) of claim 1, wherein the test and measurement device (10) is further configured to
simulate one or more additional test devices to obtain additional machine learning models and to aggregate the machine learning models from the one or more test devices (102; 104; 106; 108) and the additional machine learning models and to evaluate the quality of the local learning models based on the aggregated learning model.

4. The test and measurement system (100) of claim 1, further comprising a radio frequency interface or an emulator for a radio frequency interface to establish a connection with the one or more test devices (102; 104; 106; 108).

5. The test and measurement system (100) of claim 1, further comprising a server simulator (56) for simulating a federated learning data server in cooperation with the one or more test devices (102; 104; 106; 108) which is configured to exchange data with the one or more test devices (102; 104; 106; 108).

6. The test and measurement system (100) of claim 1, further comprising a uni-or bidirectional channel simulator (58) for simulating a time-variable or time-constant transmission channel between the test and measurement device (10) and the one or more test devices (102; 104; 106; 108), wherein the channel simulator (58) is configured to simulate one or more effects from the group of linear distortions, non-linear distortions, bit errors, communication delays, or data throughput limitations.

7. The test and measurement system (100) of claim 1, further comprising one or more device simulators (52; 60) for simulating one or more additional devices with additional learning models, wherein the device simulator (52; 60) is configured to simulate, as an additional device, one or more elements of the group of one or more further test devices, one or more reference devices, one or more unreliable devices, one or more interfering devices, or one or more adverse devices.

8. The test and measurement system (100) of claim 7, wherein the device simulator (52; 60) is configured to receive, via a software interface, a user-defined model specification, a user-defined model training, a specification for a model test, and/or a user-defined trained model.

9. The test and measurement system (100) of claim 1, further comprising a software interface for communicating a user-defined model specification and/or a specification for a model test.

10. The test and measurement system (10) of claim 1, further comprising a software interface for importing a user-defined trained model.

11. The test and measurement system (100) of claim 1, further comprising one or more software interfaces for communicating a user-defined model specification, a user-defined model aggregation, and/or a specification for a model test.

12. The test and measurement system (100) of claim 1, further comprising a monitoring and reporting unit (62).

13. The test and measurement system (100) of claim 12, wherein the monitoring and reporting unit (62) is configured to display reporting positions on a built-in display.

14. The test and measurement system (100) of claim 12, wherein the monitoring and reporting unit (62) is configured to monitor and report the order of the transmission of the data required for the training process, if applicable a time of a transmission of the data required for the training process, the frequency of a transmission of the data required for the training process, the size of the packets used for the transmission of the data required for the training process, and/or qualitative/quantitative parameters indicating the progress of the training.

15. The test and measurement system (100) of claim 1, further comprising one or more ports for coupling the one or more test devices (102; 104; 106; 108) via a radio frequency cable.

16. The test and measurement system (100) of claim 1, wherein one or more additional simulation and/or communication components are fixedly installed in the test and measurement device (10) and have an interface for communicating with the one or more test devices (102; 104; 106; 108).

17. The test and measurement system (100) of claim 1, coupled to the one or more test devices (102; 104; 106; 108).

18. A test and measurement method (20) for evaluating learning models of one or more test devices (102; 104; 106; 108), comprising the steps of:
generating (22) stimuli data for the one or more test devices (102; 104; 106; 108), wherein the one or more test devices (102; 104; 106; 108) use machine learning models,
providing (24) the stimuli data to the one or more test devices (102; 104; 106; 108) to train one or more local machine learning models by the one or more test devices (102; 104; 106; 108) based on the stimuli data,
receiving (26) learning model data about the one or more trained machine learning models from the one or more test devices (102; 104; 106; 108), and
evaluating (28) a quality of the one or more trained machine learning models based on the learning model data.

19. A machine-readable medium having a program code for performing, when the program code is executed on a computer, a processor, or a programmable hardware component, a test and measurement method (20) for evaluating learning models of one or more test devices (102; 104; 106; 108), comprising the steps of:
generating (22) stimuli data for the one or more test devices (102; 104; 106; 108), wherein the one or more test devices (102; 104; 106; 108) use machine learning models,
providing (24) the stimuli data to the one or more test devices (102; 104; 106; 108) to train one or more local machine learning models by the one or more test devices (102; 104; 106; 108) based on the stimuli data,
receiving (26) learning model data about the one or more trained machine learning models from the one or more test devices (102; 104; 106; 108), and evaluating (28) a quality of the one or more trained machine learning models based on the learning model data.
